(19) United States
(12) Patent Application Publication
(10) Pub. No.: US 2024/0355982 A1
(43) Pub. Date: Oct. 24, 2024

(54) FLEXIBLE TAPE AND DISPLAY MODULE

(71) Applicant: Guangzhou China Star Optoelectronics Semiconductor Display Technology Co., LTD., Guangzhou (CN)

(72) Inventor: Jubin LI, Guangzhou (CN)

(73) Assignee: Guangzhou China Star Optoelectronics Semiconductor Display Technology Co., LTD., Guangzhou (CN)

(21) Appl. No.: 18/522,298

(22) Filed: Nov. 29, 2023

(30) Foreign Application Priority Data
Apr. 23, 2023 (CN) 202310447970.5

(51) Int. Cl. H01L 33/62; H01L 25/075

(52) U.S. Cl. CPC H01L 33/62; H01L 25/0753

(57) ABSTRACT

A flexible tape for connecting a first terminal of a first surface and a second terminal of a second surface of a display panel. The surfaces are arranged opposite to each other. The flexible tape includes a flexible base and metal traces. At least some traces connect the terminals. A maximum line width of the traces is a first line width. A maximum line distance between two adjacent ones of the traces is a first line distance. A minimum line width of the first terminal is a second line width. A minimum line distance of the first terminal is a second line distance. An alignment deviation exists for the first and second terminals. The first line width is less than a difference between the second line distance and the alignment deviation, the first line distance is less than a difference between the second line width and the alignment deviation.

### CROSS-REFERENCE TO RELATED APPLICATIONS

This application claims the benefit of priority of Chinese Patent Application No. 202310447970.5, filed on Apr. 23, 2023, the contents of which are all incorporated by reference as if fully set forth herein in their entirety.

### TECHNICAL FIELD

The present disclosure relates to the field of display technologies, and in particular, to a flexible tape and a display module.

### BACKGROUND

Mini-LED (sub-millimeter light-emitting diode) display devices and micro-LED (micro-light-emitting diode) display devices are widely used due to advantages, such as self-luminance, high brightness, high contrast, high resolution and color saturation, long service life, fast response speed, and low power consumption. To achieve seamless splicing of conventional glass-based mini-LED and micro-LED display panels, a backbinding technology is generally used to reduce a splicing seam width. Specifically, connection terminals are provided on two sides of a glass substrate, and then the connection terminals on two sides of the glass substrate are connected through a front wire, a side wire, and a back wire. However, a front wire, a side wire and a back wire of a conventional display device need to be etched in three times, and process steps are complex. In addition, in a process of laser etching of the side wire, due to low alignment accuracy, position offset of the side wire occurs, and two adjacent front wires and adjacent back wires are connected through the side wire, resulting in a short circuit of the adjacent front wires and adjacent back wires. As a result, a yield rate of the display device is affected.

Therefore, technical problems of complex process steps of the side wire and a short circuit between adjacent wires caused by low alignment accuracy of the side wire exist in the conventional display device

### SUMMARY

Embodiments of the present disclosure provide a flexible tape and a display module.

In an aspect of the present disclosure, provided is a flexible tape. The flexible tape is configured to connect a first terminal of a first surface and a second terminal of a second surface of a display panel. The first surface and the second surface are arranged opposite to each other on the display panel. The flexible tape includes a flexible base; and metal traces arranged on a side of the flexible base, at least some of the metal traces are configured to connect the first terminal and the second terminal. A maximum line width of the metal traces is a first line width. A maximum line distance between two adjacent ones of the metal traces is a first line distance. A minimum line width of the first terminal is a second line width. A minimum line distance of the first terminal is a second line distance. An alignment deviation exists for the first terminal and the second terminal. The first line width is less than a difference between the second line distance and the alignment deviation. The first line distance is less than a difference between the second line width and the alignment deviation.

In another aspect of the present disclosure, provided is a display module. The display module includes a flexible tape. The flexible tape is configured to connect a first terminal of a first surface and a second terminal of a second surface of a display panel. The first surface and the second surface are arranged opposite to each other on the display panel. The flexible tape includes a flexible base; and metal traces arranged on a side of the flexible base, at least some of the metal traces are configured to connect the first terminal and the second terminal. A maximum line width of the metal traces is a first line width. A maximum line distance between two adjacent ones of the metal traces is a first line distance. A minimum line width of the first terminal is a second line width. A minimum line distance of the first terminal is a second line distance. An alignment deviation exists for the first terminal and the second terminal. The first line width is less than a difference between the second line distance and the alignment deviation. The first line distance is less than a difference between the second line width and the alignment deviation. The display panel includes a substrate, a first terminal and a second terminal. The substrate includes a first surface and a second surface that are arranged opposite to each other as well as a side surface connected to the first surface and the second surface. The first terminal is arranged on the first surface of the substrate. The second terminal is arranged on the second surface of the substrate. The second terminal is correspondingly arranged with the first terminal. The flexible tape is disposed along the first surface, the side surface and the second surface, the metal traces are arranged on a side of the flexible base adjacent to the substrate, and at least some of the metal traces connect the first terminal and the second terminal. On a side of the first surface, the metal traces are arranged between the first terminal and the flexible base. On a side of the second surface, the metal traces are arranged between the second terminal and the flexible base.

### BRIEF DESCRIPTION OF THE DRAWINGS

The following describes specific embodiments of the present disclosure in detail with reference to the accompanying drawings, to make the technical solutions and other beneficial effects of the present disclosure obvious.

FIG. 1 is a schematic diagram of a conventional display device.

FIG. 2 is a schematic diagram of a flexible tape according to an embodiment of the present disclosure.

FIG. 3 is a first schematic diagram of a display module according to an embodiment of the present disclosure.

FIG. 4 is a second schematic diagram of a display module according to an embodiment of the present disclosure.

FIG. 5 is an exploded view of the display panel in FIG. 3.

FIG. 6 is a third schematic diagram of a display module according to an embodiment of the present disclosure.

FIG. 7 is a fourth schematic diagram of a display module according to an embodiment of the present disclosure.

FIG. 8 is a fifth schematic diagram of a display module according to an embodiment of the present disclosure.

FIG. 9 is a sixth schematic diagram of a display module according to an embodiment of the present disclosure.

FIG. 10 is a schematic diagram of a display apparatus according to an embodiment of the present disclosure.

### DETAILED DESCRIPTION

The following clearly and completely describes the technical solutions in embodiments of the present disclosure with reference to the accompanying drawings in embodiments of the present disclosure. Apparently, the described embodiments are merely some embodiments rather than all the embodiments of the present disclosure. All other embodiments obtained by a person skilled in the art according to the embodiments of the present disclosure without creative efforts shall fall within the protection scope of the present disclosure.

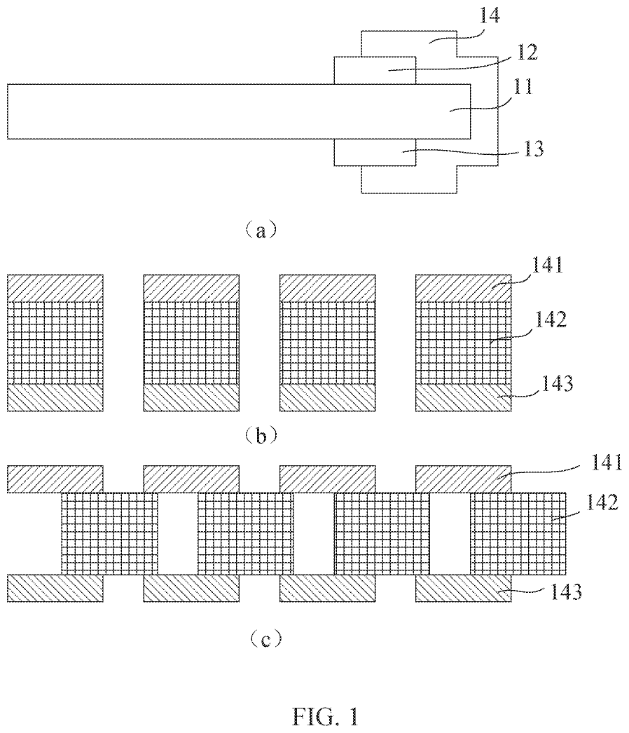

As shown in FIG. 1, section (a) in FIG. 1 is a cross sectional schematic view of a conventional display device, section (b) in FIG. 1 is a first schematic diagram of a wire 14 in the conventional display device, and section (c) in FIG. 1 is a second schematic diagram of the wire 14 in the conventional display device.

As shown in FIG. 1, to narrow a splicing seam of a conventional mini-LED (sub-millimeter light-emitting diode)/micro-LED (micro-light-emitting diode) display device, a backbinding technology is used. Specifically, in the conventional mini-LED/micro-LED display devices, a front terminal 12 is arranged on the front of a glass substrate 11, so that the front terminal 12 is connected to a mini-LED/micro-LED light emitting unit. A back terminal 13 is arranged on the back of the glass substrate 11, so that the back terminal 13 is connected to a driver chip. Then the front terminal 12 and the back terminal 13 are connected through a wire 14, to achieve a display function of the mini-LED/micro-LED display devices. A conventional preparation method of the wire 14 includes laser etching. This method requires etching of a front wire 141, a side wire 142 and a back wire 143 separately. For example, common process steps are as follows. First, a metal layer is arranged close to an edge of the glass substrate 11. A preparation method may be film forming processes, for example, printing, physical vapor deposition, electroplating, chemical plating. After film forming, patterning of a metal trace is achieved by laser etching. Because the metal trace is involved with three surfaces, namely a front surface, a side surface, and a back surface, laser etching needs to be performed in three times. Finally, the trace is encapsulated and protected, to improve resistance of the metal trace to anti-vapor intrusion and to mechanical shocks. The process steps are complex. In addition, because a traditional alignment terminal cannot be used for alignment when a metal trace on the side surface is prepared, alignment accuracy is low when etching is performed on metal on a side surface of the glass substrate 11, resulting in a problem of left and right offset of the side wire. Specifically, as shown in section (b) in FIG. 1, ideally, the side wire 142 is aligned with the front wire 141 and the back wire 143. However, due to misalignment in an etching process of the side wire 142, as shown in section (c) in FIG. 1, the side wire 142 is connected to the adjacent front wire 141 and back wire 143 in an actual state, resulting in a short circuit of the wire 14 and a reduced yield rate of the display device. Therefore, technical problems of complex process steps of the side wire and a short circuit between adjacent wires caused by low alignment accuracy of the side wire exist in the conventional display device.

For the foregoing technical problems, an embodiment of the present disclosure provides a flexible tape and a display apparatus, to resolve the foregoing technical problems.

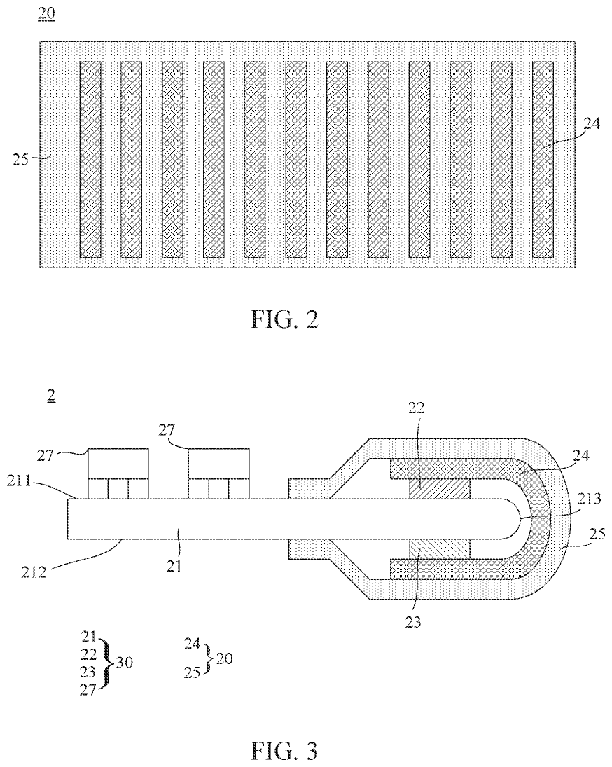

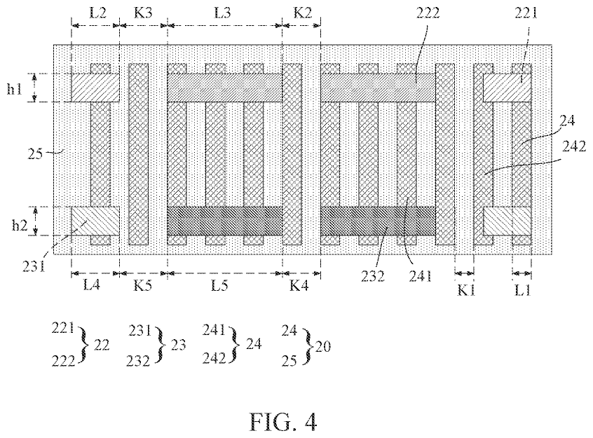

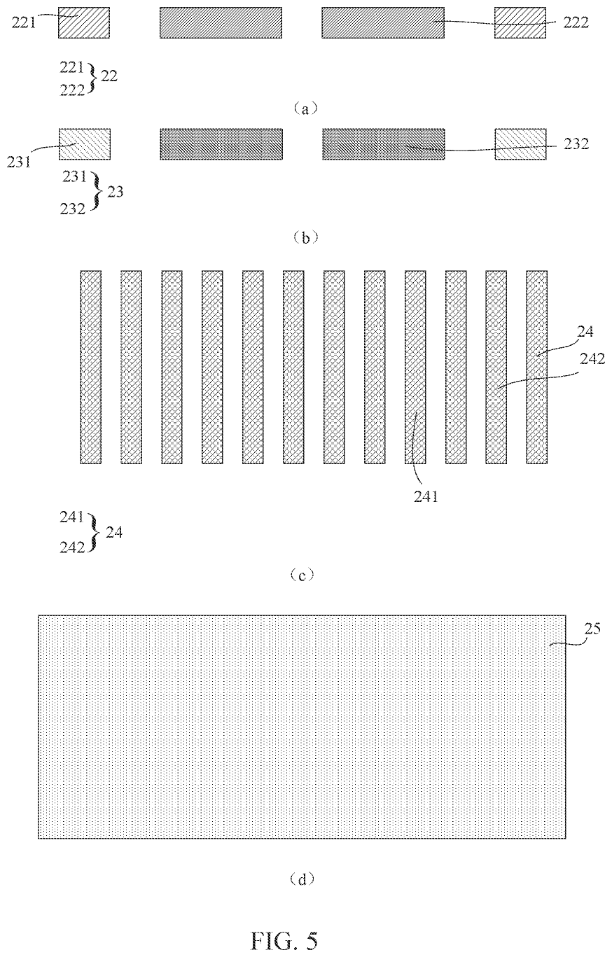

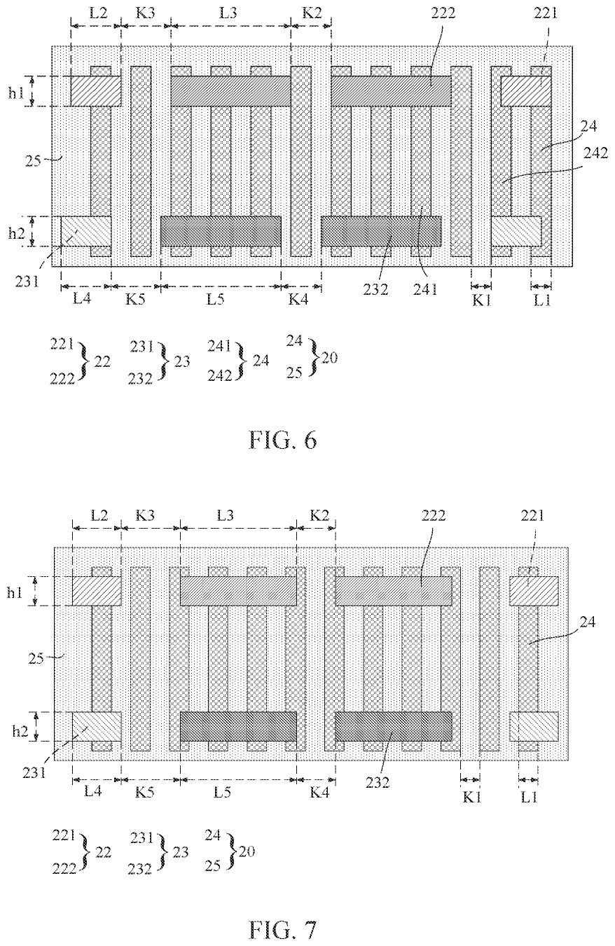

FIG. 2 is a schematic diagram of a flexible tape according to an embodiment of the present disclosure. FIG. 3 is a first schematic diagram of a display module according to an embodiment of the present disclosure. FIG. 4 is a second schematic diagram of a display module according to an embodiment of the present disclosure. FIG. 5 is an exploded view of the display module in FIG. 4, wherein section (a) in FIG. 5 is a schematic diagram of a first terminal 22, section (b) in FIG. 5 is a schematic diagram of a second terminal 23, section (c) in FIG. 5 is a schematic diagram of a metal trace 24, and section (d) in FIG. 5 is a schematic diagram of a flexible base 25. FIG. 6 is a third schematic diagram of a display module according to an embodiment of the present disclosure.

As shown in FIGS. 2 to 6, an embodiment of the present disclosure provides a flexible tape. The flexible tape 20 is configured to connect a first terminal 22 of a first surface 211 and a second terminal 23 of a second surface 212 that are arranged opposite to each other on a display panel 30. The flexible tape 20 includes a flexible base 25; and metal traces 24 arranged on a side of the flexible base 25, wherein at least some metal traces 24 are configured to connect the first terminal 22 and the second terminal 23.

The maximum line width of the metal traces 24 is a first line width L1. The maximum line distance between two adjacent metal traces 24 is a first line distance K1. The minimum line width of the first terminal 22 is a second line width (for example, a line width L2 of a first sub-terminal 221). The minimum line distance of the first terminal 22 is a second line distance K2. Alignment deviation L6 exists between the first terminal 22 and the second terminal 23. The first line width L1 is less than a difference between the second line distance K2 and the alignment deviation L6 (that is, L1<K2-L6). The first line distance K1 is less than a difference between the second line width and the alignment deviation L6 (that is, K1<L2-L6).

An embodiment of the present disclosure provides a flexible tape. The flexible tape connects a first terminal and a second terminal through metal traces. A front wire, a side wire and a back wire do not need to be arranged separately. This improves a preparation efficiency of the display module. The flexible tape can protect the metal traces and the terminals without needing to provide a side scaling adhesive. This further improves the preparation efficiency of the display module. A first line width is less than a difference between a second line distance and alignment deviation. A first line distance is less than a difference between a second line width and the alignment deviation. Even if the metal traces are offset, the metal traces can neither connect two first terminals, nor connect two second terminals, and the metal traces do not connect a first terminal and a second terminal that do not correspond to each other. In this way, a short circuit between a first terminal and a second terminal that are adjacent to each other can be avoided. In addition, when the metal traces are offset, at least one metal trace can connect the first terminal and the second terminal, so that the first terminal and the second terminal can be connected normally, the display module can function normally, and a yield rate of the display module can be improved.

It should be noted that, the first surface 211 and the second surface 212 are two surfaces that are arranged opposite to each other. The first surface 211 and the second surface 212 may be the front and back of the display panel respectively. For example, the first surface 211 is a surface where a light emitting unit is arranged. The second surface 212 is a surface where a driver chip is bound.

It should be noted that, the first terminal being correspondingly arranged with the second terminal means that when the metal traces connect the first terminal and the second terminal, each first terminal corresponds to a second terminal. Line widths of the first terminal and the second terminal that are correspondingly arranged with each other may be equal. A second line distance between two adjacent second terminals is equal to a second line distance between two corresponding first terminals. An offset distance of projection of the first terminal and the second terminal that are arranged correspondingly on the substrate is alignment deviation of the first terminal and the second terminal. For example, in FIG. 4, each first terminal 22 is correspondingly arranged with a second terminal 23. In FIG. 6, the offset distance between the first terminal 22 and the corresponding second terminal 23 is the alignment deviation L6 between the first terminal 22 and the second terminal.

It should be noted that, the maximum line width of metal traces 24 means: If line widths of the metal traces 24 are not equal, a line width of a metal trace 24 with a maximum line width is the maximum line width of the metal traces 24, that is, the line width of the metal trace 24 with the maximum line width is a first line width. If line widths of the metal traces 24 are equal, a line width of any metal trace 24 is the maximum line width of the metal traces 24, that is, the line width of any metal trace 24 is a first line width. In the accompanying drawings in embodiments of the present disclosure, a case in which the line widths of the metal traces 24 are equal is used for illustration, so that the line widths of the metal traces 24 are each first line width L1.

It should be noted that, the maximum line distance between two adjacent metal traces 24 means the distances that exists between every two adjacent metal traces 24. If distances between two adjacent metal traces 24 are not equal, the maximum line distance between two adjacent metal traces 24 is a distance between two metal traces 24 with a maximum line distance. If distances between every two adjacent metal traces 24 are equal, a distance between every two adjacent metal traces 24 is the maximum line distance between two adjacent metal traces 24. In the accompanying drawings in embodiments of the present disclosure, a case in which the line distances between every two adjacent metal traces 24 are equal is used for illustration, so that each of the line distances between every two adjacent metal traces 24 is the first line distance K1.

It should be noted that, as shown in FIG. 6, it can be seen that the first terminal 22 includes a first sub-terminal 221 and a second sub-terminal 222, and a line width L2 of the first sub-terminal 221 is less than a line width L3 of the second sub-terminal 222, so that the minimum line width of the first terminal 22 is L2. It can be understood that only first terminals with two line widths are shown in FIG. 6. If the display panel includes sub-terminals with multiple line widths, the minimum line width of the first terminal is a line width of a sub-terminal with a minimum line width.

It should be noted that, as shown in FIG. 6, if a line distance K2 between a second sub-terminal 222 and a second sub-terminal 222 is less than a line distance K3 between a first sub-terminal 221 and a second sub-terminal 222, so that the minimum line distance of the first terminal 22 is K2. It can be understood that only first terminals with two line distances are shown in FIG. 6. If first terminals of the display panel include multiple different line distances, the minimum line distance of the first terminal is a line distance between two adjacent sub-terminals with a minimum line distance. Similarly, if a line distance K4 between a fourth sub-terminal 232 and a fourth sub-terminal 232 is less than a line distance K5 between a fourth sub-terminal 232 and a third sub-terminal 231, the minimum line distance of the second terminal is K4.

It should be noted that, in FIG. 6, an example in which a line distance between a second sub-terminal and a second sub-terminal is less than a line distance between a first sub-terminal and a second sub-terminal is used for description. However, this embodiment of the present disclosure is not limited thereto. For example, a line distance between a first sub-terminal and a second sub-terminal is less than a line distance between a second sub-terminal and a second sub-terminal, or a line distance between a first sub-terminal and a second sub-terminal is less than a line distance between a first sub-terminal and a first sub-terminal. Similarly, for arrangement manners of the third sub-terminal and the fourth sub-terminal, refer to the first sub-terminal and the second sub-terminal.

Specifically, FIG. 6 shows that a second sub-terminal is arranged adjacent to a second sub-terminal. However, this embodiment of the present disclosure is not limited thereto. For example, a second sub-terminal is arranged adjacent to a first sub-terminal, and a first sub-terminal is arranged adjacent to a first sub-terminal. Similarly, for arrangement manners of the third sub-terminal and the fourth sub-terminal, refer to the first sub-terminal and the second sub-terminal.

It should be noted that, Alignment deviation of the first terminal and the second terminal means that when the first terminal and the second terminal are prepared, specific deviation exists between the first terminal and the second terminal due to an impact of alignment accuracy. For example, in FIG. 6, the second terminal 23 is offset to the left by L6 compared with the first terminal 22, so that the alignment deviation between the first terminal and the second terminal is L6. It can be understood that alignment deviation between any first terminal and second terminal that are arranged correspondingly is L6.

In an embodiment, line widths of at least some metal traces are not equal. For example, line widths of some metal traces are greater than line widths of other metal traces.

In an embodiment, at least some line distances between two adjacent metal traces are not equal. For example, some line distances between two adjacent metal traces are the first line distance, and other line distances between two adjacent metal traces are less than the first line distance.

For the problem that line widths of the metal traces are not equal, resulting in a small number of metal traces, and total impedance of the metal traces connecting the first terminal and the second terminal is large, in an embodiment, as shown in FIG. 4, line widths of any two metal traces 24 are equal, that is, line widths of the metal traces 24 are each first line width L1. The line widths of the metal traces are equal, so that more metal traces with a same width can be arranged. Accordingly, a total line width of metal traces between any group of a first terminal and a corresponding second terminal are closer to a line width of a first terminal or a second terminal that are connected by the metal traces. In addition, lengths of a contact part of the metal traces and the first terminal and a contact part of the metal traces and the second terminal are respectively a line length of the first terminal and a line length of the second terminal, so that a contact area between the metal traces and the first terminal and a contact area between the metal traces and the second terminal are large. This can avoid problems, such as excessive voltage drops and fusing traces during signal transmission, and improve a yield rate of the display panel.

For the problem that line distances between the metal traces are not equal, resulting in a small number of metal traces, and total impedance of the metal traces connecting the first terminal and the second terminal is large, in an embodiment, as shown in FIG. 4, line distances between every two adjacent metal traces 24 are equal, that is, each of the line distances between every two adjacent metal traces 24 is the first line distance K1. The line distances between every two adjacent metal traces are equal, so that more metal traces with a same width can be arranged. Accordingly, a total line width of metal traces between any group of a first terminal and a corresponding second terminal are closer to a line width of a first terminal or a second terminal that are connected by the metal traces. In addition, lengths of a contact part of the metal traces and the first terminal and a contact part of the metal traces and the second terminal are respectively a line length of the first terminal and a line length of the second terminal, so that a contact area between the metal traces and the first terminal and a contact area between the metal traces and the second terminal are large. This can avoid problems, such as excessive voltage drops and fusing traces during signal transmission, and improve a yield rate of the display panel.

In the foregoing embodiments, an example in which line widths of any two metal traces are equal and an example in which line distances between every two adjacent metal traces are equal are used for description separately. However, this embodiment of the present disclosure is not limited thereto. For example, line widths of any two metal traces are equal and line distances between every two adjacent metal traces are equal, so that more metal traces with a same width are arranged. Accordingly, a total line width of metal traces between any group of a first terminal and a corresponding second terminal are closer to a line width of a first terminal or a second terminal that are connected by the metal traces. This can avoid problems, such as excessive voltage drops and fusing traces during signal transmission, and improve a yield rate of the display panel.

For the problem that an insufficient water-oxygen-proof ability of a flexible tape may lead to water-oxygen intrusion, in an embodiment, as shown in FIG. 9, the flexible tape 20 further includes a waterproof layer 29. The waterproof layer 29 is arranged between the flexible base 25 and the metal traces 24. Alternatively, the waterproof layer 29 is arranged on a side of the flexible base 25 away from the metal traces 24. The waterproof layer is arranged, so that the waterproof layer can further protect the metal traces and terminals, avoid water-oxygen intrusion and mechanical shocks, and improve a yield rate of the display panel.

Specifically, when the waterproof layer 29 is arranged, a projection area of the waterproof layer 29 on the flexible base 25 is equal to an area of the flexible base 25. The flexible base is covered by an entire surface of the waterproof layer, so that the flexible tape can be sealed by the waterproof layer, to avoid water-oxygen intrusion.

Specifically, in FIG. 9, an example in which the waterproof layer 29 is arranged on a side of the flexible base 25 away from the metal traces 24 is used for description. However, this embodiment of the present disclosure is not limited thereto. For example, the waterproof layer may be arranged between the flexible base and the metal traces.

Specifically, a material of the waterproof layer includes but is not limited to one of inorganic materials, epoxy resin, or fluorocarbon resin.

In addition, an embodiment of the present disclosure provides a display module. The display module includes the flexible tape as described in any of the foregoing embodiments and a display panel.

As shown in FIGS. 3 to 6, an embodiment of the present disclosure provides a display module. The display module 2 includes a flexible tape 20 and a display panel 30.

The display panel 30 includes a substrate 21, a first terminal 22, and a second terminal 23. The substrate 21 includes a first surface 211 and a second surface 212 that are arranged opposite to each other as well as a side surface 213 connected to the first surface 211 and the second surface 212. The first terminal 22 is arranged on the first surface 211 of the substrate 21. The second terminal 23 is arranged on the second surface 212 of the substrate 21. The second terminal 23 is correspondingly arranged with the first terminal 22.

The flexible tape 20 extends along the first surface 211 and the side surface 213 to the second surface 212. The flexible tape 20 includes a flexible base 25 and metal traces 24. The metal traces 24 are arranged on a side of the flexible base 25 close to the substrate 21. At least some of the metal traces 24 connect the first terminal 22 and the second terminal 23.

On a side of the first surface 211, the metal traces 24 are arranged between the first terminal 22 and the flexible base 25. On a side of the second surface 212, the metal traces 24 are arranged between the second terminal 23 and the flexible base 25. The maximum line width of the metal traces 24 is a first line width L1. The maximum line distance between two adjacent metal traces 24 is a first line distance K1. The minimum line width of the first terminal 22 is a second line width (for example, a line width L2 of a first sub-terminal 221). The minimum line distance of the first terminal 22 is a second line distance K2. Alignment deviation L6 exists between the first terminal 22 and the second terminal 23. The first line width L1 is less than a difference between the second line distance K2 and the alignment deviation L6 (that is, L1<K2-L6). The first line distance K1 is less than a difference between the second line width and the alignment deviation L6 (that is, K1<L2-L6).

An embodiment of the present disclosure provides a display module. The display module connects a first terminal and a second terminal through metal traces on a flexible tape. A front wire, a side wire and a back wire do not need to be arranged separately, so that a preparation efficiency of the display module is improved. The flexible tape can protect the metal traces and the terminals without needing to provide a side sealing adhesive. This further improves the preparation efficiency of the display module. A first line width is less than a difference between a second line distance and alignment deviation, and first line distance is less than a difference between a second line width and the alignment deviation. Therefore, even if the metal traces are offset, the metal traces can neither connect two first terminals, nor connect two second terminals, and the metal traces do not connect a first terminal and a second terminal that do not correspond to each other. In this way, a short circuit between a first terminal and a second terminal that are adjacent to each other can be avoided. In addition, when the metal traces are offset, at least one metal trace can connect the first terminal and the second terminal, so that the first terminal and the second terminal can be connected normally, the display module can function normally, and a yield rate of the display module can be improved.

Specifically, as shown in FIG. 3 and FIG. 4, it can be seen that in the present disclosure, the flexible tape 20 is attached to two sides of the substrate. The metal traces 24 on the flexible tape 20 connect the first terminal 22 and the second terminal 23. The metal traces 24 is formed on the flexible base 25. When the metal traces 24 are formed, a front wire, a side wire, and a back wire do not need to formed separately in three times. A metal layer can be directly etched to form the metal traces 24. This reduces a process procedure of the display module, and improves a preparation efficiency of the display module. Some of the metal traces corresponding to the first terminal, the second terminal, and the side surface of the display panel are multiple parts of the metal traces, so that a problem of misalignment does not exist. This avoids a problem of a short circuit caused by misalignment of the side wire with the front wire and the back wire. In addition, the flexible tape 20 can protect the metal traces 24, the first terminal 22, and the second terminal 23 without needing to provide an additional side sealing adhesive. This further reduces the process procedure of the display module, and improves the preparation efficiency of the display module.

In addition, as shown in FIGS. 3 to 6, in an embodiment of the present disclosure, the first line width L1 is less than a difference between the second line distance K2 and the alignment deviation L6, so that a metal trace 24 can contact at most one of first terminals 22 that are adjacent to each other, and does not contact a second terminal 23 that does not correspond to the metal trace 24. This avoids a short circuit between a first terminal and a second terminal that are adjacent to each other. The first line distance K1 is less than a difference between the second line width and the alignment deviation L6, so that at least one metal trace 24 between the first terminal and the corresponding second terminal 23 needs to exist. In this way, the first terminal 22 and the second terminal 23 are connected normally, the display panel can function normally, a short circuit between first terminals, a short circuit between second terminals, and a short circuit between the first terminal and the second terminal that does not correspond to the first terminal are avoided, and the yield rate of the display module is improved. When the tape is attached, this effect can be achieved without left and right alignment, so that the preparation efficiency of the display module is improved.

In addition, in comparison with providing the side wire, laser scribing needs to be performed on the side wire, and accuracy is low. In the present disclosure, the metal traces are formed on the flexible base, so that the process is more mature and the accuracy is higher. This can further reduce line widths of the metal traces and line distances between the metal traces, and can increase thickness of the metal traces. Therefore, voltage drops of the metal traces are reduced, signal loss between the first terminal and the second terminal is small, and the yield rate of the display module is improved. In addition, when line widths of the metal traces and line distances between the metal traces are small, a flexible tape can be suitable for various terminals with different distances, so that a flexible tape can be suitable for various display panels. The flexible tape is easy to be made into coils, cut to different sizes, easy to transport, and suitable for various products.

For a problem that if the alignment deviation between the first terminal and the second terminal is greater than the line width of the metal trace, the first terminal and the second terminal cannot be connected, in an embodiment, as shown in FIG. 6, line widths of the metal traces 24 are greater than the alignment deviation L6 between the first terminal 22 and the second terminal 23. The line widths of the metal traces are greater than the alignment deviation between the first terminal and the second terminal, so that the metal traces can connect the first terminal and the second terminal, a case in which a signal cannot be transmitted because the first terminal and the second terminal are not connected is avoided, and the yield rate of the display module is improved.

In an embodiment, line widths of the metal traces are less than or equal to the alignment deviation between the first terminal and the second terminal.

In an embodiment, as shown in FIG. 3 and FIG. 4, the alignment deviation between the first terminal 22 and the second terminal 23 is 0. A projection of the first terminal 22 on the substrate 21 overlaps with a projection of the second terminal 23 on the substrate 21. The alignment deviation between the first terminal and the second terminal is 0, and the projection of the first terminal on the substrate overlaps with the projection of the second terminal on the substrate. In this way, when the metal traces are prepared, the line widths of metal traces and/or line distances between metal traces can be set greater, so that a problem of circuit breaking or excessive impedance caused by too small line widths of the metal traces is avoided, and a problem of a short circuit caused by too small line distances between the metal traces is also avoided. Alternatively, more metal traces are provided, so that problems, such as excessive voltage drops and fusing traces during signal transmission can be avoided, and the yield rate of the display module is improved.

Specifically, for example, if the alignment deviation between the first terminal and the second terminal is 1 micrometer, and the minimum line distance of the first terminal is 6 micrometers, line widths of the metal traces need to be less than 5 micrometers. If the alignment deviation between the first terminal and the second terminal is 0, and the minimum line distance of the first terminal is 6 micrometers, the line widths of the metal traces only need to be less than 6 micrometers. The line widths of the metal traces can be increased. Similarly, line distances between the metal traces and a number of the metal traces can be increased.

In an embodiment, the alignment deviation between the first terminal and the second terminal is less than or equal to 5 micrometers. Specifically, when a laser machine is used for alignment, specific alignment accuracy deviation may exist, and alignment deviation between the first terminal and the second terminal may further exist. If the alignment deviation between the first terminal and the second terminal is less than or equal to 5 micrometers, a case in which if excessive alignment deviation between the first terminal and the second terminal exists, the metal traces cannot connect a first terminal and a second terminal that correspond to each other can be avoided, thereby improving the yield rate of the display module.

In an embodiment, as shown in FIG. 4, some of the metal traces are insulated from the first terminal 22, and the metal traces 24 insulated from the first terminal 22 are insulated from the second terminal 23. The metal traces are insulated from the first terminal, and the metal traces are insulated from the second terminal, so that the metal traces are avoided to connect the first terminal and the second terminal that are adjacent to each other, and the yield rate of the display module is improved.

Specifically, as shown in FIG. 4, in comparison with a current display device, a side wire located between two adjacent front wires connects adjacent front wires and adjacent back wires, resulting in a short circuit of the display device and a low yield rate of the display device. In an embodiment of the present disclosure, the first line width is less than a difference between the second line distance and the alignment deviation, and the first line distance is less than a difference between the second line width and the alignment deviation, so that when the metal traces are offset, metal traces between two adjacent first terminals are floating, and the metal traces between two adjacent first terminals do not connect any first terminal and any second terminal. This can avoid that the metal traces connect adjacent first terminals and/or adjacent second terminals, thereby improving the yield rate of the display module.

In an embodiment, as shown in FIGS. 3 to 6, the metal traces 24 includes a first metal trace 241. A contact area between the first metal trace 241 and the first terminal 22 is equal to a product L1xh1 of a line width L1 of the first metal trace 241 and a line length h1 of the first terminal 22. A contact area between the first metal trace 241 and the second terminal 23 is less than or equal to a product L1xh2 of the line width L1 of the first metal trace 241 and a line length h2 of the second terminal 23. The contact area between the first metal trace and the first terminal is the maximum overlapping area between the first metal trace and the first terminal, and the contact area between the first metal trace and the second terminal is the maximum overlapping area between the first metal trace and the second terminal, so that a good connection effect between the first metal trace and the first terminal and the second terminal is obtained. This avoids that poor signal transmission is caused due to a poor connection effect between the first terminal and the second terminal resulting in, and improves the yield rate of the display module. The contact area between the first metal trace and the first terminal is the maximum overlapping area between the first metal trace and the first terminal, and the first metal trace connects the second terminal, so that the first metal trace can connect the first terminal and the second terminal, and display module can function normally.

Specifically, in an embodiment of the present disclosure, neither orientation of the first surface and the second surface nor specific orientation of the first terminal and the second terminal are defined. Therefore, the first terminal may be a terminal connected to a binding terminal on a display panel side, and the second terminal may be a terminal connected to a binding terminal on a driver chip side. Alternatively, the second terminal may be a terminal connected to a binding terminal on a display panel side, and the first terminal may be a terminal connected to a binding terminal on a driver chip side. It can be understood that a design of the first terminal may be applied to the second terminal, and a design of the second terminal may be applied to the first terminal. For example, the contact area between the first metal trace 241 and the first terminal 22 is less than or equal to the product L1xh1 of the line width L1 of the first metal trace 241 and the line length h1 of the first terminal 22. The contact area between the first metal trace 241 and the second terminal 23 is equal to the product L1xh2 of the line width L1 of the first metal trace 241 and the line length h2 of the second terminal 23. In the following embodiments, for the design, refer to the foregoing descriptions. Details are not described in the following embodiments again.

Specifically, as shown in FIG. 4, it can be seen that an area of an overlapping part of the projection of the first metal trace 241 on the flexible base 25 and the projection of the first terminal 22 on the flexible base 25 is the product of the line width L1 of the first metal trace 241 and the line length h1 of the first terminal 22. An area of an overlapping part of the projection of the first metal trace 241 on the flexible base 25 and the projection of the second terminal 23 on the flexible base 25 is the product of the line width L1 of the first metal trace 241 and the line length h2 of the second terminal 23, so that the contact area between the first metal trace 241 and the first terminal 22 and the second terminal 23 is the largest. As shown in FIG. 6, it can be seen that the area of the overlapping part of the projection of the first metal trace 241 on the flexible base 25 and the projection of the first terminal 22 on the flexible base 25 is the product of the line width L1 of the first metal trace 241 and the line length h1 of the first terminal 22. The area of the overlapping part of the projection of the first metal trace 241 on the flexible base 25 and the projection of the second terminal 23 on the flexible base 25 is less than the product of the line width L1 of the first metal trace 241 and the line length h2 of the second terminal 23, so that the first metal trace 241 can connect the first terminal 22 and the second terminal 23.

Specifically, if alignment deviation between the first terminal and the second terminal is 0, a contact area between some of the metal traces and the first terminal is equal to a product of the line width of the metal trace with the line length of the first terminal, and a contact area between the metal traces and the second terminal is equal to a product of the line width of the metal trace with the line length of the second terminal. If the alignment deviation between the first terminal and the second terminal is greater than 0, the contact area between some of the metal traces and the first terminal is equal to the product of the line width of the metal trace with the line length of the first terminal, and the contact area between the metal traces and the second terminal is equal to the product of the line width of the metal trace with the line length of the second terminal. In addition, the contact area between some of the metal traces and the first terminal can be equal to the product of the line width of the metal trace and the line length of the first terminal, and the contact area between the metal trace and the second terminal is less than the product of the line width of the metal trace and the line length of the second terminal.

In an embodiment, as shown in FIGS. 3 to 6, the metal traces 24 include a second metal trace 242. A contact area between the second metal trace 242 and the first terminal 22 is less than a product L1xh1 of a line width L1 of the second metal trace 242 and the line length h1 of the first terminal 22. A contact area between the second metal trace 242 and the second terminal 23 is less than a product L1xh2 of the line width L1 of the second metal trace 242 and the line length h2 of the second terminal 23. The contact area between the second metal trace and the first terminal is less than the maximum overlapping area between the second metal trace and the first terminal, and the contact area between the second metal trace and the second terminal is less than the maximum overlapping area between the second metal trace and the second terminal, so that the second metal trace can normally connect the first terminal when the second metal trace and the first terminal are misaligned. In addition, the second metal trace does not connect an adjacent first terminal. This avoids a short circuit between terminals in the display panel and improves the yield rate of the display module.

Specifically, if a contact area between the metal traces and the first terminal is less than the product of the line width of the metal trace and the line length of the first terminal, the contact area between the metal traces and the first terminal can be equal to the contact area between the metal traces and the second terminal, or the contact area between the metal traces and the first terminal can be greater than the contact area between the metal traces and the second terminal. For example, the metal traces connect the first terminal, the metal traces are insulated from the second terminal, and the contact area between the metal traces and the first terminal can be less than the contact area between the metal traces and the second terminal, as shown in FIG. 6.

In an embodiment, as shown in FIG. 6, the first terminal 22 includes a first sub-terminal 221 and a second sub-terminal 222.

The second terminal 23 includes a third sub-terminal 231 and a fourth sub-terminal 232. The third sub-terminal 231 is correspondingly arranged with the first sub-terminal 221, and the fourth sub-terminal 232 is correspondingly arranged with the second sub-terminal 222.

A line width L2 of the first sub-terminal 221 is equal to a line width LA of the third sub-terminal 231. A line width L3 of the second sub-terminal 222 is equal to a line width L5 of the fourth sub-terminal 232. The line width L3 of the second sub-terminal 222 is greater than the line width L2 of the first sub-terminal 221. A number of the metal traces 24 connecting the first sub-terminal 221 and the third sub-terminal 231 is less than or equal to a number of the metal traces 24 connecting the second sub-terminal 222 and the fourth sub-terminal 232. The first terminal includes a first sub-terminal and a second sub-terminal with different widths, and the corresponding second terminal includes a third sub-terminal and a fourth sub-terminal with different widths, so that when the metal traces connect the first sub-terminal and the third sub-terminal correspondingly, and the metal traces connect the second sub-terminal and the fourth sub-terminal correspondingly, the second sub-terminal and the fourth sub-terminal with greater widths can be connected through more metal traces. This avoids problems such as fusing metal traces caused by excessive current between the second sub-terminal and the fourth sub-terminal, and improves the yield rate of the display module.

Specifically, when the first terminal and the second terminal are arranged, signals inputted by different signal lines in the display panel are different, for example, voltages inputted by some of the signal lines are high, and voltages inputted by some of the signal lines are low. Therefore, line widths of the signal lines and line distances between the signal lines need to be adjusted accordingly, so that line widths and line distances of terminals connected to the signal lines are different.

For a case that line widths of the first terminal are different, in this embodiment of the present disclosure, line widths of the metal traces can be equal and line distances between every two adjacent metal traces are equal. In this way, when the metal traces connect a first sub-terminal and a second sub-terminal with different widths, a total contact area between metal traces of any group of a first terminal and a corresponding second terminal and the first terminal is closer to a cross-sectional area of the first terminal connected by the metal traces. The total contact area between any group of the metal traces between the first terminal and the corresponding second terminal and the second terminal is closer to a cross-sectional area of the second terminal connected by the metal traces. This can avoid problems, such as excessive voltage drops and fusing traces during signal transmission, and improve the yield rate of the display panel.

Specifically, in the present disclosure, the metal traces are formed on the flexible base, so that preparation accuracy of the metal traces is high. The line width of the metal trace and the line distance between the metal traces can be further reduced, thickness of the metal traces can be increased, and the number of the metal traces between the first terminal and the second terminal can be further increased. This avoids problems, such as excessive voltage drops and fusing traces during signal transmission, and improves the yield rate of the display panel.

Specifically, the total contact area between the metal traces and the first terminal is a sum of contact areas between the metal traces and the first terminal. The total contact area between the metal traces and the second terminal is a sum of contact areas between the metal traces and the second terminal.

Specifically, as shown in FIG. 6, a number of metal traces 24 connecting the first sub-terminal 221 and the third sub-terminal 231 can be one or two, and a number of metal traces 24 connecting the second sub-terminal 222 and the fourth sub-terminal 232 can be 3. In this case, when widths of the second sub-terminal 222 and the fourth sub-terminal 232 are great, a total width of metal traces connecting the second sub-terminal and the fourth sub-terminal can also be great, and the total contact area between the second sub-terminal and the fourth sub-terminal and the metal traces is large. This avoids problems, such as excessive voltage drops and fusing traces during signal transmission, reduces loss of signal transmission, reduces power consumption of the display panel, and improves the yield rate of the display module.

Specifically, the total contact area between metal traces between any group of the first terminal and the corresponding second terminal and the first terminal is one-half to nine-tenths of the cross-sectional area of the first terminal, and the total contact area between the metal traces between any group of the first terminal and the corresponding second terminal and the second terminal is one-half to nine-tenths of the cross-sectional area of the second terminal.

Specifically, the line width of the metal trace can be increased to increase the contact area between the metal traces and the first terminal and the second terminal. For example, the line width of the metal trace is one-quarter to one-half of the line width of the first terminal to increase the contact area between the metal traces and the first terminal and the second terminal. In addition, impedance of the metal traces and a risk of breaking the metal traces are reduced.

Specifically, a line distance between adjacent metal traces can be reduced, for example, the line distance between the metal traces is one-half to one-tenth of the minimum line distance of the first terminal, so that a setting density of the metal traces is high, the contact area between the metal traces and the first terminal and the second terminal is increased, and loss of an electrical signal from the first terminal to the second terminal is reduced.

Specifically, the line width of the metal trace and the line distance between the metal traces can be also reduced at the same time, so that the line width of the metal trace and the line distance between the metal traces are as small as possible, and the setting density of the metal traces is high. The total contact area between the metal traces between any group of the first terminal and the second terminal and the first terminal is closer to the cross-sectional area of the first terminal. The total contact area between the metal traces between any group of the first terminal and the second terminal and the second terminal is closer to the cross-sectional area of the second terminal. In this way, total impedance of the metal traces connecting the first terminal and the second terminal is low, the risk of breaking the metal traces is reduced, the loss of electrical signals is reduced, and the yield rate of the display panel is improved.

Specifically, in FIG. 6, an example in which the number of metal traces connecting the first sub-terminal and the third sub-terminal is less than the number of metal traces connecting the second sub-terminal and the fourth sub-terminal is used for description. However, this embodiment of the present disclosure is not limited thereto. For example, the number of metal traces connecting the first sub-terminal and the third sub-terminal is equal to the number of metal traces connecting the second sub-terminal and the fourth sub-terminal.

In an embodiment, as shown in FIG. 7, the line width L2 of the first sub-terminal 221 is less than a sum of the line width L1 of the corresponding metal trace 24 and the line distance K1 of the corresponding metal trace 24, that is, L2 is less than L1+K1. The first sub-terminal 221 is connected to the third sub-terminal 231 through a metal trace 24. The line width of the first sub-terminal is less than the sum of the line width of the corresponding metal trace and the line distance between the corresponding metal traces, so that only one metal trace can be connected to the first sub-terminal and the third sub-terminal. This avoids a short circuit between adjacent terminals caused when the metal trace is connected to an adjacent first sub-terminal.

Specifically, in the foregoing embodiments, an example in which the line width of the first sub-terminal is less than the sum of the line width of the metal trace and the line distance between the metal traces is used for detailed description. However, this embodiment of the present disclosure is not limited thereto. For example, the line width of the first sub-terminal may be greater than or equal to the sum of the line width of the metal trace and the line distance between the metal traces.

in an embodiment, as shown in FIG. 7, a line width L3 of the second sub-terminal 222 is greater than a sum of twice of a line width L1 of a corresponding metal trace 24 and a line distance K1 of the corresponding metal trace 24. The second sub-terminal 222 is connected to the fourth sub-terminal 232 through at least two metal traces 24. A line width of the second sub-terminal is greater than a sum of twice of a line width of a corresponding metal trace and a line distance between the corresponding metal traces, so that the second sub-terminal and the fourth sub-terminal can be connected through at least two metal traces. In this way, when the second sub-terminal and the fourth sub-terminal transmit signals through the metal trace, problems are avoided, such as high power consumption due to excessive voltage drops of the metal traces, and fusing metal traces due to excessive current. This reduces power consumption of the display module and improves the yield rate of the display module.

Specifically, in the foregoing embodiments, an example in which the line width of the second sub-terminal is greater than the sum of twice of the line width of the metal trace and the line distance between the corresponding metal traces is used for detailed description. However, this embodiment of the present disclosure is not limited thereto. For example, the line width of the second sub-terminal is greater than the sum of the line width of the metal trace and the line distance between the metal traces, and the line width of the second sub-terminal is less than or equal to the sum of twice of the line width of the metal trace and the line distance between the corresponding metal traces.

In an embodiment, as shown in FIG. 6, some of the first sub-terminals 221 and the third sub-terminals 231 are connected through a metal trace 24, and some of the first sub-terminals 221 and the third sub-terminals 231 are connected through multiple metal traces 24.

In an embodiment, some of the second sub-terminals and the fourth sub-terminals are connected through a metal trace, and some of the second sub-terminals and the fourth sub-terminals are connected through multiple metal traces.

In an embodiment, a line width of a first terminal is equal to a line width of a corresponding second terminal, and a line distance between two adjacent first terminals is equal to a line distance between corresponding two second terminals. A line width of a first terminal is equal to a line width of a corresponding second terminal, and a line distance between two adjacent first terminals is equal to a line distance between corresponding two second terminals, so that when the first terminal and the second terminal are arranged, the first terminal is correspondingly arranged with the second terminal to transmit signals.

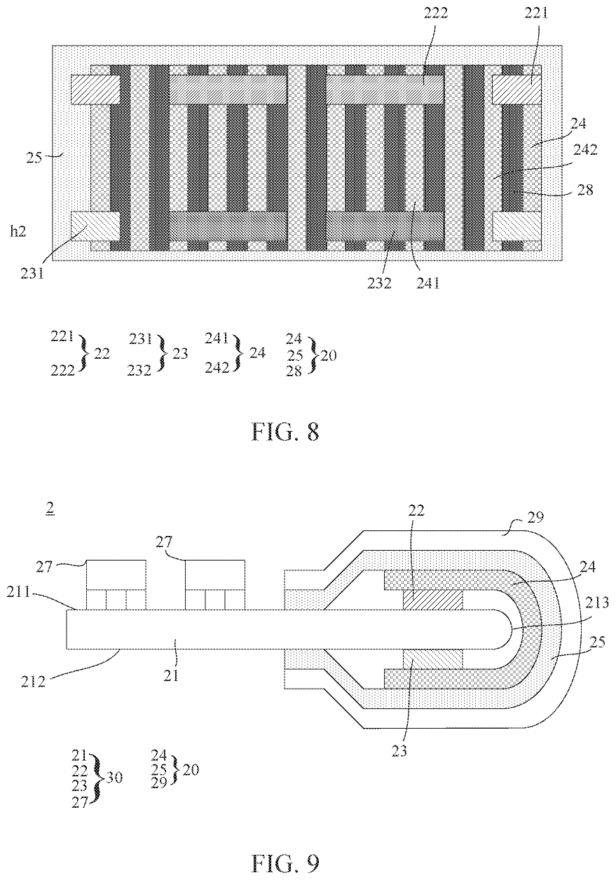

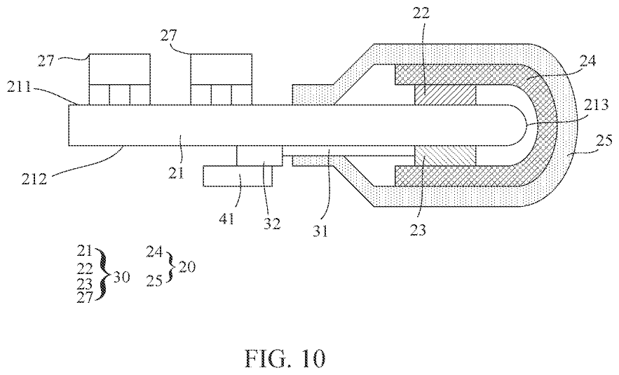

For a problem of a short circuit between metal traces caused by a short line distance between metal traces, in an embodiment, as shown in FIG. 8, the flexible tape 20 further includes an insulation adhesive 28. The insulation adhesive 28 is at least provided between adjacent metal traces 24. The metal traces 24 are in direct contact with the first terminal 22 in a region corresponding to the first terminal 22. The metal traces 24 are in direct contact with the second terminal 23 in a region corresponding to the second terminal 23. The insulation adhesive is provided and the insulation adhesive is at least provided between adjacent metal traces, to enable the insulation adhesive to avoid a short circuit between metal traces. In addition, the metal traces can contact first terminals, and the metal traces can be in direct contact with the second terminal, so that the metal traces can connect the first terminal and the second terminal, and the display panel can function normally.

Specifically, in the present disclosure, the insulation adhesive is provided on the flexible tape to enable the flexible tape to be stably attached to the substrate, to avoid falling off of the flexible tape. To avoid a short circuit between the metal traces, an insulation adhesive is used as an adhesive material, to improve the yield rate of the display panel.

Specifically, four edges of the flexible tape are provided with an insulation adhesive. The four edges of the flexible tape are provided with the insulation adhesive, so that after the flexible tape is attached to the substrate, a lower part of the flexible tape is in a sealed state to avoid water vapor intrusion, side sealing adhesive does not need to be provide for the flexible tape, and the preparation efficiency of the display panel is improved.

Specifically, as shown in FIG. 8, an example in which the insulation adhesive 28 is provided between adjacent metal traces 24 is used for description. However, this embodiment of the present disclosure is not limited thereto. For example, a front surface of the insulation adhesive can be covered on the flexible base and the metal traces. When the flexible tape is attached to the substrate, a hot pressing process is applied at a position where the metal traces overlap with the first terminal and the second terminal. In this way, the metal traces 24 connect the first terminal and the second terminal without an insulation adhesive, and the metal traces can be in direct contact with the first terminal and the second terminal to ensure that the display panel functions normally.

Specifically, a material of the insulation adhesive includes but is not limited to polyacrylate, acrylic resin, and epoxy resin.

In an embodiment, the display module further includes an anisotropic conductive adhesive. The anisotropic conductive adhesive is provided between the first terminal and the metal traces, and the anisotropic conductive adhesive is provided between the second terminal and the metal traces. The anisotropic conductive adhesive is provided, so that a yield rate of connection between metal traces and the first terminal and the second terminal is high, and the yield rate of the display module is improved.

In an embodiment, along a direction of the first surface, the side surface to the second surface, the line length of the metal trace is greater than a sum of the line length of the first terminal, the line length of the second terminal, and the distance between the first terminal and the second terminal. The line length of the metal trace is greater than a sum of the line length of the first terminal, the line length of the second terminal, and the distance between the first terminal and the second terminal, so that the metal traces can completely connect the first terminal and the second terminal. The contact area between the metal traces and the first terminal and the second terminal is increased, to avoid problems, such as excessive voltage drops and fusing traces during signal transmission, and improve the yield rate of the display panel.

In an embodiment, the line width of the metal trace ranges from 2 micrometers to 50 micrometers, and the line distance between the metal traces ranges from 2 micrometers to 50 micrometers.

In an embodiment, the line width of the first terminal ranges from 5 micrometers to 500 micrometers, and the line distance between the first terminals ranges from 5 micrometers to 51 micrometers.

In an embodiment, a material of the substrate includes glass. A material of the substrate includes glass, so that the first terminal and the second terminal can be prepared with a same mark for alignment, to ensure that the first terminal and the second terminal can be aligned within an alignment deviation range.

In an embodiment, the material of the flexible base includes one of polyethylene terephthalate, polyimide, or polyethylene naphthalate.

In an embodiment, the material of the metal trace includes either copper or aluminum.

In an embodiment, as shown in FIG. 3, the display panel further includes a light emitting unit 27. The light emitting unit 27 includes a mini-LED light emitting unit and a micro-LED light emitting unit.

The foregoing embodiments separately describe in detail the alignment deviation of the first terminal and the second terminal, a contact manner between the metal traces and the first terminal and the second terminal, a connection manner between the first sub-terminal, the second sub-terminal, the third sub-terminal, the fourth sub-terminal and the metal traces, and the like. However, this embodiment of the present disclosure is not limited thereto. If the embodiments do not conflict with each other, the embodiments may be combined. For example, when the alignment deviation between the first terminal and the second terminal is 0, some of the metal traces can be insulated from the first terminal, and the metal traces insulated from the first terminal are insulated from the second terminal. For example, the line width of the first terminal ranges from 5 micrometers to 500 micrometers, and the line distance between the first terminals ranges from 5 micrometers to 51 micrometers. The line width of the first terminal is equal to the line width of the corresponding second terminal, and the line distance between adjacent two first terminals is equal to the line distance between corresponding two second terminals.

In addition, an embodiment of the present disclosure provides a display module preparation method. The display module preparation method prepares the display module as described in any of the foregoing embodiments. The display module preparation method includes preparing metal traces on a flexible base to obtain a flexible tape; providing a display panel, wherein the display panel includes a substrate; and attaching the flexible tape to a side surface of the substrate and bending the side surface, to enable the metal traces to connect a first terminal and a second terminal.

Specifically, the steps of preparing metal traces on a flexible base to obtain a flexible tape further include coating the metal traces with an insulation adhesive.

Specifically, when the metal traces are coated with an adhesive insulation adhesive, the insulation adhesive may be coated between the metal traces, may be coated to avoid a region where the metal traces contact terminals, or may be coated on the entire surface. If the insulation adhesive is coated on the entire surface, the flexible tape is attached in a hot pressing manner when the flexible tape is attached to the substrate. The flexible tape is attached in a hot pressing manner, to avoid the insulation adhesive on the metal traces. In this way, the metal traces are in normal contact with the first terminal and the second terminal, and the yield rate of the display module is improved.

In addition, an embodiment of the present disclosure provides a display apparatus. The display apparatus includes the display module as described in any of the foregoing embodiments and a driver chip.

Specifically, as shown in FIG. 9, the display module further includes a fanout line 31 and a binding terminal 32. The fanout line 31 connects the binding terminal 32 and a second terminal 23, and the binding terminal 32 is connected to the driver chip 41.

According to the foregoing embodiments, it can be seen that:

The present disclosure provides a flexible tape and a display module. The flexible tape connects a first terminal and a second terminal through metal traces. A front wire, a side wire, and a back wire do not need to be arranged separately. This improves a preparation efficiency of the display module. The flexible tape can protect the metal traces and the terminals without needing to provide a side sealing adhesive. This further improves the preparation efficiency of the display module. A first line width is less than a difference between a second line distance and alignment deviation, and a first line distance is less than a difference between a second line width and alignment deviation. Even if the metal traces are offset, the metal traces can neither connect two first terminals, nor connect two second terminals, and the metal traces do not connect a first terminal and a second terminal that do not correspond to each other. In this way, a short circuit between a first terminal and a second terminal that are adjacent to each other can be avoided. In addition, when the metal traces are offset, at least one metal trace can connect the first terminal and the second terminal, so that the first terminal and the second terminal can be connected normally, the display module can function normally, and a yield rate of the display module can be improved.

In the foregoing embodiments, the embodiments are described with different emphasis. For a part that is not described in detail in an embodiment, refer to related descriptions in other embodiments.

The flexible tape and the display module provided in embodiments of the present disclosure are described above in detail. The principles and implementations of the present disclosure are described by using specific examples in this specification, and the descriptions of the foregoing embodiments are merely intended to help understand the technical solutions and core ideas of the present disclosure. It should be understood by a person skilled in the art that, modifications may still be made to the technical solutions described in the foregoing embodiments, or equivalent replacements may be made to the part of the technical features. These modifications or replacements will not cause the essence of corresponding technical solutions to depart from the scope of the technical solutions in the embodiments of the present disclosure.

What is claimed is:

1. A flexible tape for connecting a first terminal of a first surface and a second terminal of a second surface of a display panel, the first surface and the second surface being arranged opposite to each other on the display panel, the flexible tape comprising:
a flexible base; and
metal traces arranged on a side of the flexible base, at least some of the metal traces configured to connect the first terminal and the second terminal,
wherein a maximum line width of the metal traces is a first line width, a maximum line distance between two adjacent ones of the metal traces is a first line distance, a minimum line width of the first terminal is a second line width, a minimum line distance of the first terminal is a second line distance, an alignment deviation exists for the first terminal and the second terminal, the first line width is less than a difference between the second line distance and the alignment deviation, and the first line distance is less than a difference between the second line width and the alignment deviation.

2. The flexible tape of claim 1, wherein line widths of any two of the metal traces are equal, and line distances between every two adjacent ones of the metal traces are equal.

3. The flexible tape of claim 1, wherein the flexible tape further comprises a waterproof layer, and the waterproof layer is arranged between the flexible base and the metal traces.

4. The flexible tape of claim 1, wherein the flexible tape further comprises a waterproof layer, and the waterproof layer is arranged on a side of the flexible base away from the metal traces.

5. A display module, comprising a flexible tape for connecting a first terminal of a first surface and a second terminal of a second surface of a display panel, the first surface and the second surface being arranged opposite to each other on the display panel, the flexible tape comprising:
a flexible base; and
metal traces arranged on a side of the flexible base, at least some of the metal traces configured to connect the first terminal and the second terminal,
wherein a maximum line width of the metal traces is a first line width, a maximum line distance between two adjacent ones of the metal traces is a first line distance, a minimum line width of the first terminal is a second line width, a minimum line distance of the first terminal is a second line distance, an alignment deviation exists for the first terminal and the second terminal, the first line width is less than a difference between the second line distance and the alignment deviation, and the first line distance is less than a difference between the second line width and the alignment deviation,
wherein the display panel comprises a substrate, a first terminal, and a second terminal, the substrate comprises a first surface and a second surface that are arranged opposite to each other as well as a side surface connected to the first surface and the second surface, the first terminal is arranged on the first surface of the substrate, the second terminal is arranged on the second surface of the substrate, and the second terminal is correspondingly arranged with the first terminal,
wherein the flexible tape is disposed along the first surface, the side surface and the second surface, the metal traces are arranged on a side of the flexible base adjacent to the substrate, and at least some of the metal traces connect the first terminal and the second terminal, and
wherein on a side of the first surface, the metal traces are arranged between the first terminal and the flexible base, and on a side of the second surface, the metal traces are arranged between the second terminal and the flexible base.

6. The display module of claim 5, wherein line widths of any two of the metal traces are equal, and line distances between every two adjacent ones of the metal traces are equal.

7. The display module of claim 5, wherein the flexible tape further comprises a waterproof layer, and the waterproof layer is arranged between the flexible base and the metal traces.

8. The display module of claim 5, wherein the flexible tape further comprises a waterproof layer, and the waterproof layer is arranged on a side of the flexible base away from the metal traces.

9. The display module of claim 5, wherein the alignment deviation for the first terminal and the second terminal is 0, and a projection of the first terminal on the substrate overlaps with a projection of the second terminal on the substrate.

10. The display module of claim 5, wherein some of the metal traces are insulated from the first terminal, and the metal traces insulated from the first terminal are insulated from the second terminal.

11. The display module of claim 5, wherein the metal traces comprises a first metal trace, a contact area between the first metal trace and the first terminal is equal to a product of a line width of the first metal trace and a line length of the first terminal, and a contact area between the first metal trace and the second terminal is less than or equal to a product of the line width of the first metal trace and a line length of the second terminal.

12. The display module of claim 5, wherein the metal traces comprise a second metal trace, a contact area between the second metal trace and the first terminal is less than a product of a line width of the second metal trace and the line length of the first terminal, and a contact area between the second metal trace and the second terminal is less than a product of the line width of the second metal trace and the line length of the second terminal.

13. The display module of claim 5, wherein the metal traces comprises a first metal trace, a contact area between the first metal trace and the first terminal is equal to a product of a line width of the first metal trace and a line length of the first terminal, and a contact area between the first metal trace and the second terminal is less than or equal to a product of the line width of the first metal trace and a line length of the second terminal; and the metal traces comprise a second metal trace, a contact area between the second metal trace and the first terminal is less than a product of a line width of the second metal trace and the line length of the first terminal, and a contact area between the second metal trace and the second terminal is less than a product of the line width of the second metal trace and the line length of the second terminal.

14. The display module of claim 5, wherein the first terminal comprises a first sub-terminal and a second sub-terminal; and
the second terminal comprises a third sub-terminal and a fourth sub-terminal, the third sub-terminal is correspondingly arranged with the first sub-terminal, and the fourth sub-terminal is correspondingly arranged with the second sub-terminal,
wherein a line width of the first sub-terminal is equal to a line width of the third sub-terminal, a line width of the second sub-terminal is equal to a line width of the fourth sub-terminal, the line width of the second sub-terminal is greater than the line width of the first sub-terminal, and a number of the metal traces connecting the first sub-terminal and the third sub-terminal is less than or equal to a number of the metal traces connecting the second sub-terminal and the fourth sub-terminal.

15. The display module of claim 14, wherein the line width of the first sub-terminal is less than a sum of a line width of a corresponding one of the metal traces and a line distance of the corresponding metal trace, and the first sub-terminal is connected to the third sub-terminal through a metal trace.

16. The display module of claim 14, wherein the line width of the second sub-terminal is greater than a sum of twice of a line width of a corresponding one of the metal traces and a line distance of the corresponding metal trace, and the second sub-terminal is connected to the fourth sub-terminal through at least two of the metal traces.

17. The display module of claim 14, wherein the line width of the first sub-terminal is less than a sum of a line width of a corresponding one of the metal traces and a line distance of the corresponding metal trace, and the first sub-terminal is connected to the third sub-terminal through a metal trace; and the line width of the second sub-terminal is greater than a sum of twice of a line width of a corresponding one of the metal traces and a line distance of the corresponding metal trace, and the second sub-terminal is connected to the fourth sub-terminal through at least two of the metal traces.

18. The display module of claim 5, wherein the flexible tape further comprises an insulation adhesive, the insulation adhesive is disposed at least between adjacent metal traces, the metal traces are in direct contact with the first terminal in a region corresponding to the first terminal, and the metal traces are in direct contact with the second terminal in a region corresponding to the second terminal.

19. The display module of claim 5, wherein the display module further comprises an anisotropic conductive adhesive, the anisotropic conductive adhesive is disposed between the first terminal and the metal traces, and the anisotropic conductive adhesive is disposed between the second terminal and the metal traces.

20. The display module of claim 6, wherein the alignment deviation for the first terminal and the second terminal is 0, and a projection of the first terminal on the substrate overlaps with a projection of the second terminal on the substrate.
